(19) United States
(12) Patent Application Publication
(10) Pub. No.: US 2014/0002964 A1
(43) Pub. Date: Jan. 2, 2014

(54) MEMS DEVICE ENCAPSULATION WITH CORNER OR EDGE SEALS

(71) Applicants: Wenguang Li, Fremont, CA (US); Jay Sarkar, Emerald Hills, CA (US); Jianwei Liu, Fremont, CA (US); Robert Henry Wieler, San Jose, CA (US)

(72) Inventors: Wenguang Li, Fremont, CA (US); Jay Sarkar, Emerald Hills, CA (US); Jianwei Liu, Fremont, CA (US); Robert Henry Wieler, San Jose, CA (US)

(73) Assignee: QUALCOMM MEMS TECHNOLOGIES, INC., San Diego, CA (US)

(21) Appl. No.: 13/535,772

(22) Filed: Jun. 28, 2012

(51) Int. Cl. H05K 7/00; H05K 13/00

(52) U.S. Cl. 361/679.01; 29/623.1

(57) ABSTRACT

This disclosure provides systems, methods and apparatus for packaging a device, for example an electromechanical systems (EMS) device, with a seal. In one aspect, the EMS device includes a primary seal positioned around a perimeter of the EMS device and in contact with a substrate and a cover plate, and a secondary seal positioned around portions of an outer periphery of the primary seal and in contact with the substrate and the cover plate. The primary seal can have low outgassing and low permeability of water vapor, and the secondary seal can have high mechanical strength that does not degrade when adhered to glass.

### TECHNICAL FIELD

This disclosure relates generally to electromechanical systems (EMS) devices and more particularly to methods and systems for packaging EMS devices.

### DESCRIPTION OF THE RELATED TECHNOLOGY

Electromechanical systems include devices having electrical and mechanical elements, actuators, transducers, sensors, optical components (e.g., mirrors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

Device packaging in electromechanical systems can protect the functional units of the system from the environment, provide mechanical support for the system components, and provide an interface for electrical interconnections.

### SUMMARY

The systems, methods and devices of the disclosure each have several innovative aspects, no single one of which is solely responsible for the desirable attributes disclosed herein.

In some implementations, the secondary seal is positioned only around one or more corners of the outer periphery of the primary seal. In some implementations, the secondary seal has a higher moisture and heat resistance than the primary seal. In some implementations, the primary seal has lower permeability of water vapor compared to the secondary seal, where the primary seal includes a first epoxy having a permeability of water vapor less than about 20 g/m2/day across a 0.1 mm thick membrane at 60° C. and 90% humidity. In some implementations, the sealant structure has a lower permeability of water vapor relative to the primary seal. In some implementations, the secondary seal includes silane-containing adhesion promoters.

Another innovative aspect of the subject matter described in this disclosure can be implemented in an electromechanical systems apparatus. The electromechanical systems apparatus includes a substrate; an electromechanical systems device element formed on the substrate; a cover plate over the electromechanical systems device element; and a sealant structure. The sealant structure includes a continuous primary seal positioned around a perimeter of the electromechanical systems device and in contact with the substrate and the cover plate to provide a hermetically sealed environment inside, where the primary seal includes a first adhesive. The sealant structure also includes a non-continuous secondary seal positioned proximate to one or more corners of a periphery of the primary seal and in contact with the substrate and the cover plate, where the secondary seal includes a second adhesive different than the first adhesive.

In some implementations, the second adhesive has a higher mechanical strength than the first adhesive. In some implementations, the sealant structure has a peel force strength higher than 22 N/cm after 10 days at 60° C. and 90% humidity. In some implementations, the secondary seal includes inorganic particulates having greater than 75% by weight of the total weight of the secondary seal. In some implementations, the first adhesive has at least one of lower outgassing and lower permeability of water vapor than the second adhesive.

Another innovative aspect of the subject matter described in this disclosure can be implemented in an electromechanical systems apparatus. The electromechanical systems apparatus includes a substrate; an electromechanical systems device element formed on the substrate; a cover plate over the electromechanical systems device element; and a sealant structure. The sealant structure includes primary means for sealing the electromechanical systems device apparatus positioned around a perimeter of the electromechanical systems device and in contact with the substrate and the cover plate, where the primary means for sealing, the cover plate, and the substrate form a cavity within the electromechanical systems apparatus. The sealant structure also includes secondary means for sealing the electromechanical systems device apparatus positioned outside the cavity and in contact with the substrate and the cover plate, where the primary means for sealing has lower outgassing compared to the secondary means for sealing, and where the secondary means for sealing includes an adhesive having a higher mechanical strength when adhered to glass compared to the primary means for sealing.

In some implementations, the primary means for sealing has lower permeability of water vapor than the secondary means for sealing. In some implementations, the secondary means for sealing is positioned only around one or more corners of an outer periphery of the primary means for sealing.

Another innovative aspect of the subject matter described in this disclosure can be implemented in a method of manufacturing an electromechanical systems apparatus. The method includes providing an electromechanical systems device on a substrate; providing a cover plate over the electromechanical systems device; forming a primary seal around a periphery of the electromechanical systems device and in contact with the substrate and the cover plate; and forming a secondary seal around the periphery of the electromechanical systems device and in contact with the substrate and the cover plate, where the primary seal has at least one of lower outgassing and lower permeability of water compared to the secondary seal, and where the secondary seal includes an adhesive having a higher mechanical strength when adhered to glass than the primary seal.

In some implementations, forming the primary seal includes forming a continuous primary seal and providing a hermetically sealed environment inside the electromechanical systems apparatus, and forming the secondary seal includes forming a non-continuous secondary seal.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8E show examples of cross-sectional schematic illustrations of various stages in a method of making an interferometric modulator.

FIG. 9 shows an example of a cross-sectional side view of an EMS device with a primary seal and a secondary seal.

FIG. 10A shows an example of a top plan view of an EMS device with a primary seal and a secondary seal around the corners of the primary seal according to some implementations.

FIG. 10B shows an example of a top plan view of an EMS device with a primary seal and a secondary seal along the edges of the primary seal according to some implementations.

FIG. 10C shows an example of a top plan view of an EMS device with a primary seal and a secondary seal within the interior of the primary seal according to some implementations.

FIG. 11A shows an example of an image of a portion of an EMS device with a secondary seal around the corners of a primary seal according to some implementations.

FIG. 11B shows an example of an image of a portion of an EMS device with a secondary seal along the edges of a primary seal according to some implementations.

FIGS. 12A and 12B show examples of flow diagrams illustrating methods of manufacturing an EMS device.

FIGS. 13A and 13B show examples of system block diagrams illustrating a display device that includes a plurality of interferometric modulators.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. The described implementations may be implemented in any device that is configured to display an image, whether in motion (e.g., video) or stationary (e.g., still image), and whether textual, graphical or pictorial. More particularly, it is contemplated that the implementations may be implemented in or associated with a variety of electronic devices such as, but not limited to, mobile telephones, multimedia Internet enabled cellular telephones, mobile television receivers, wireless devices, smartphones, bluetooth devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (e.g., e-readers), computer monitors, auto displays (e.g., odometer display, etc.), cockpit controls and/or displays, camera view displays (e.g., display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (e.g., electromechanical systems (EMS), MEMS and non-MEMS), aesthetic structures (e.g., display of images on a piece of jewelry) and a variety of electromechanical systems devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes, electronic test equipment. Thus, the teachings are not intended to be limited to the implementations depicted solely in the Figures, but instead have wide applicability as will be readily apparent to one having ordinary skill in the art.

Some implementations described herein relate to device packaging of electromechanical systems (EMS) devices. An EMS device can include a seal between a substrate on which the device is disposed and a cover plate to provide mechanical support and to protect the EMS device from ambient conditions. Some seals provide a hermetically sealed environment inside the EMS device. A primary seal can be disposed around a perimeter of the EMS device. In some implementations, the primary seal can be an epoxy-based adhesive with low outgassing and a low permeability of water vapor. A secondary seal can be disposed around portions of an outer periphery of the primary seal, such as around one or more corner edges. In some implementations, the secondary seal can have a higher mechanical strength than the primary seal when adhered to glass and a higher moisture and heat resistance than the primary seal.

Particular implementations of the subject matter described in this disclosure can be implemented to realize one or more of the following potential advantages. The use of both a primary seal and a secondary seal provides a seal with both mechanical strength that does not degrade over time when exposed to moisture and heat, so that the EMS device does not delaminate or break apart over time, as well as low moisture permeability. If a seal for the EMS device delaminates, moisture or other environmental agents can enter the device and cause the operation of the EMS device to fail. Thus, the use of both a secondary seal and a primary seal can improve the lifetime, operation, and performance of the EMS device when compared to an EMS device with only a single seal or with primary and secondary seals of similar materials.

An example of a suitable EMS or MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

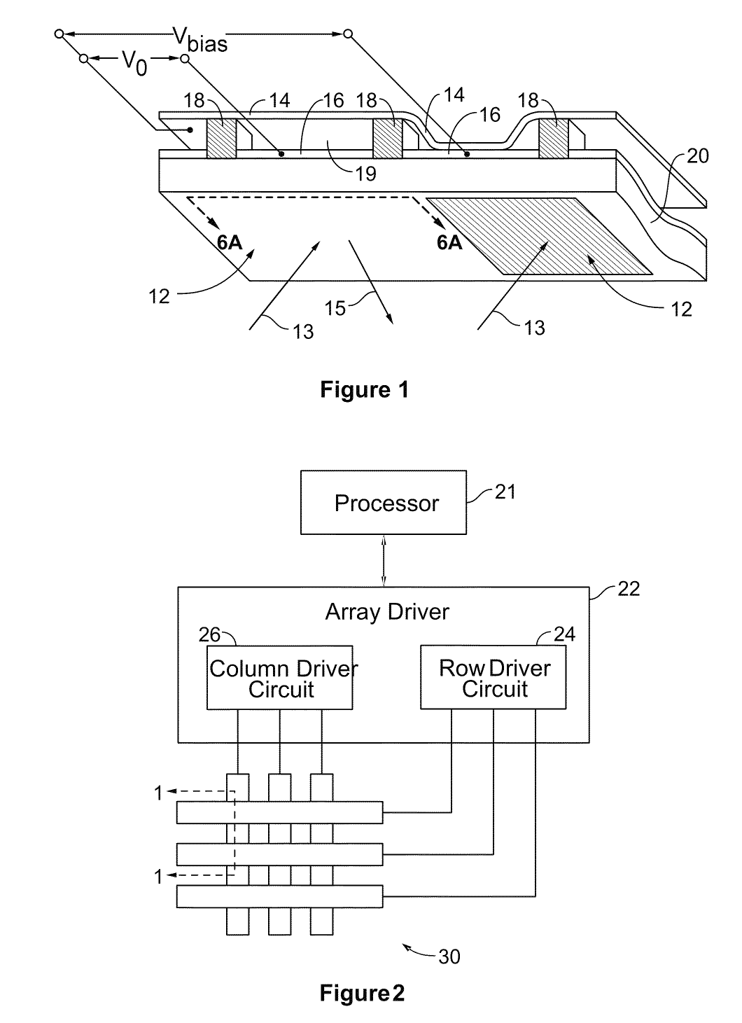

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows 13 indicating light incident upon the pixels 12, and light 15 reflecting from the IMOD 12 on the left. Although not illustrated in detail, it will be understood by one having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the IMOD 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be approximately 1-1000 um, while the gap 19 may be less than 10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the IMOD 12 on the left in FIG. 1, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated IMOD 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

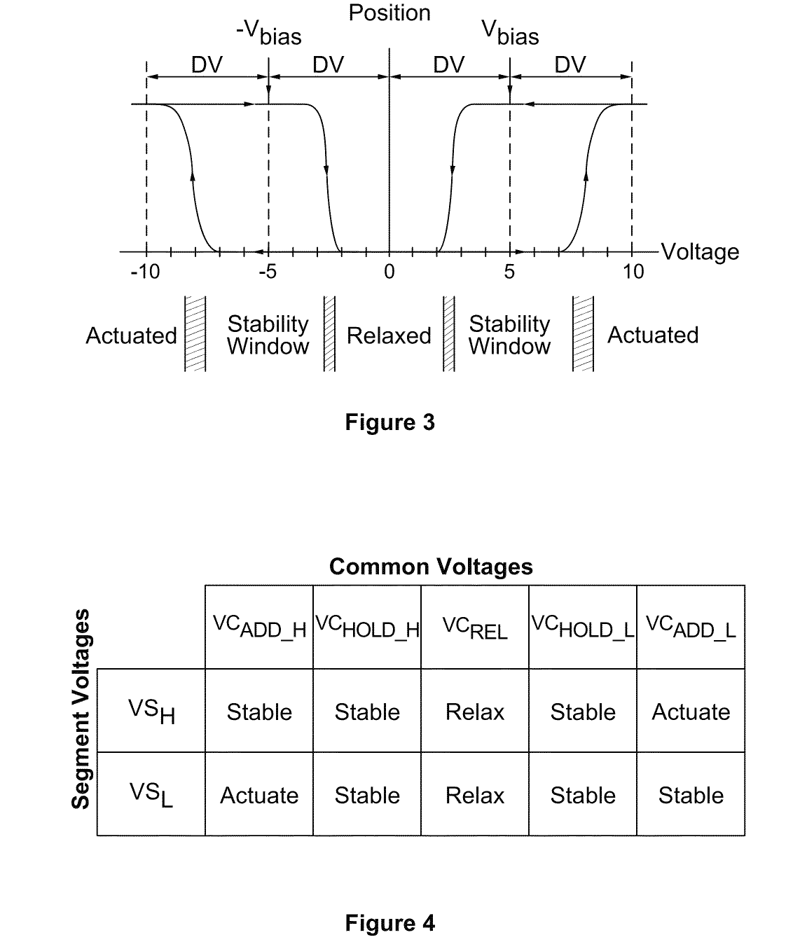

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or other software application.

The processor 21 can be configured to communicate with an array driver 22. The array driver 22 can include a row driver circuit 24 and a column driver circuit 26 that provide signals to, e.g., a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

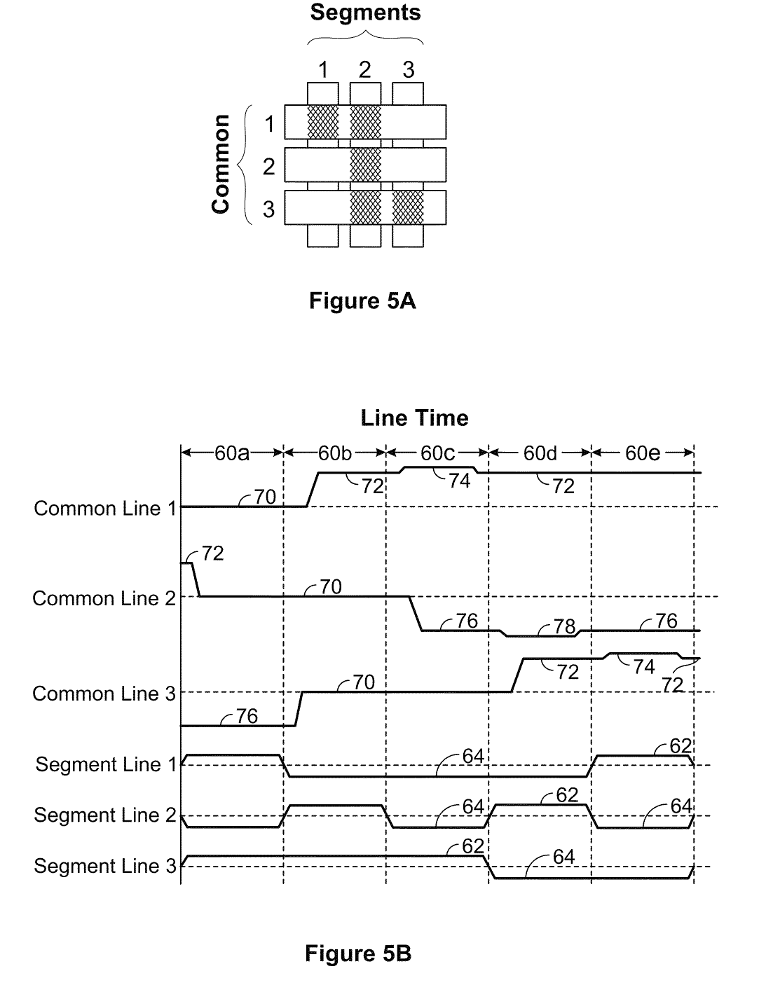

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may require, for example, about a 10-volt potential difference to cause the movable reflective layer, or mirror, to change from the relaxed state to the actuated state. When the voltage is reduced from that value, the movable reflective layer maintains its state as the voltage drops back below, e.g., 10 volts, however, the movable reflective layer does not relax completely until the voltage drops below 2 volts. Thus, a range of voltage, approximately 3 to 7 volts, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about 10 volts, and pixels that are to be relaxed are exposed to a voltage difference of near zero volts. After addressing, the pixels are exposed to a steady state or bias voltage difference of approximately 5-volts such that they remain in the previous strobing state. In this example, after being addressed, each pixel sees a potential difference within the “stability window” of about 3-7 volts. This hysteresis property feature enables the pixel design, e.g., illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

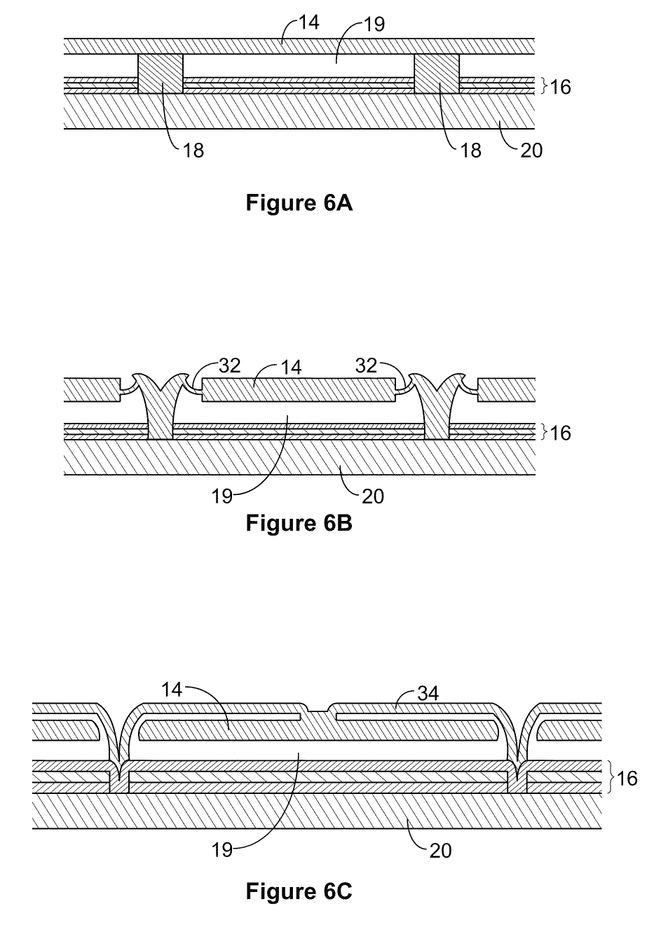

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

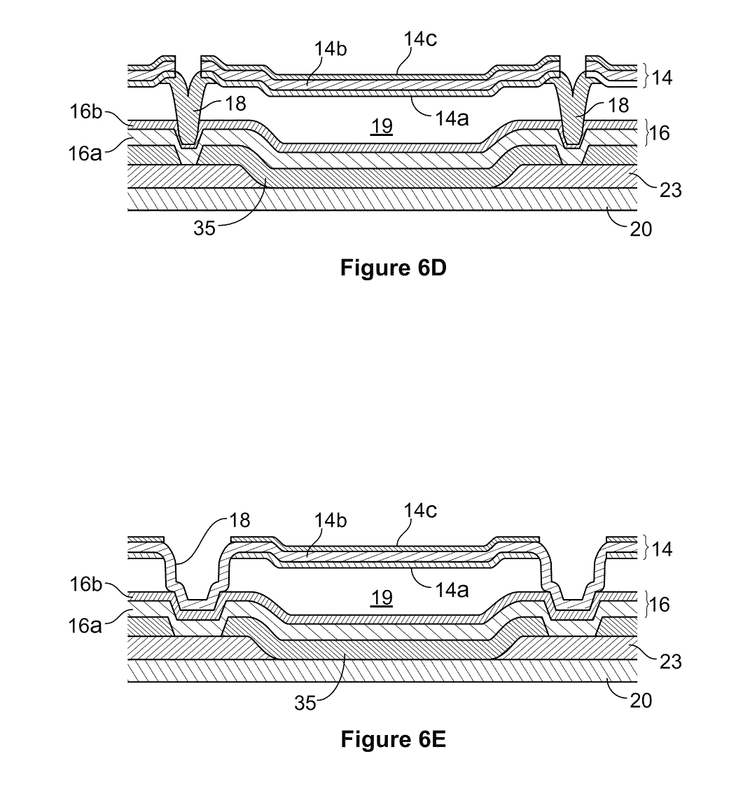

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which always produce the same polarity potential difference across the modulators. In some other implementations, signals can be used which alternate the polarity of the potential difference of the modulators. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to the, e.g., 3×3 array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, e.g., a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a, a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}—relax and VC_{HOLD}_{_{—}}_{L}—stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the necessary line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

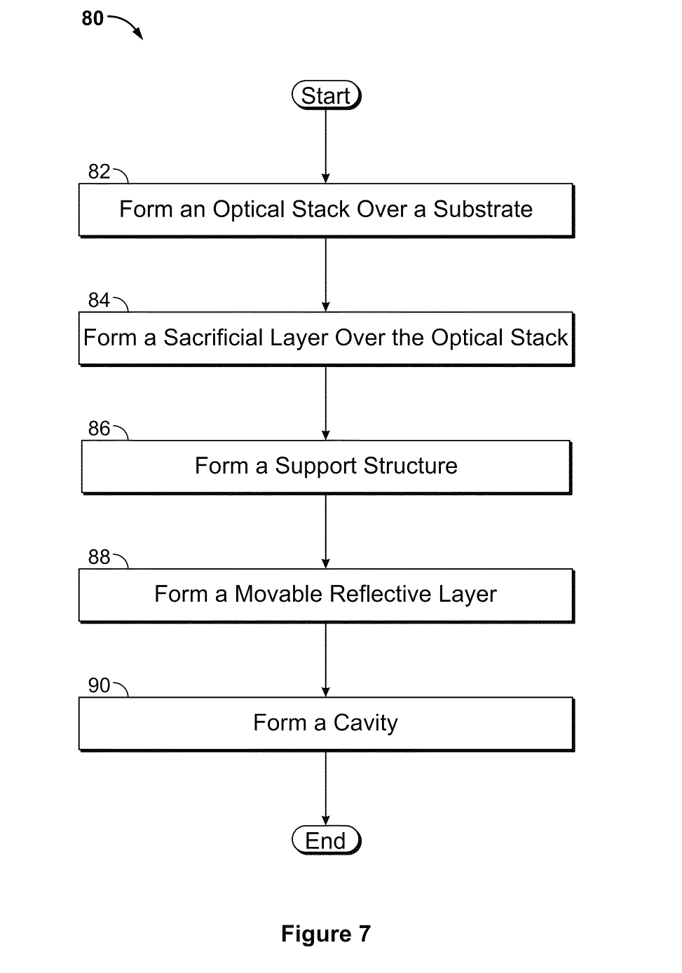

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In FIG. 6B, the movable reflective layer 14 of each IMOD is generally square or rectangular in shape and attached to supports at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, e.g., an aluminum (Al) alloy with about 0.5% copper (Cu), or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (e.g., between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, an SiO₂ layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, carbon tetrafluoromethane (CF₄) and/or oxygen (O₂) for the MoCr and SiO₂ layers and chlorine (Cl₂) and/or boron trichloride (BCl₃) for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 6E shows another example of an IMOD, where the movable reflective layer 14 is self-supporting. In contrast with FIG. 6D, the implementation of FIG. 6E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer.

In implementations such as those shown in FIGS. 6A-6E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing.

Additionally, the implementations of FIGS. 6A-6E can simplify processing, such as, e.g., patterning.

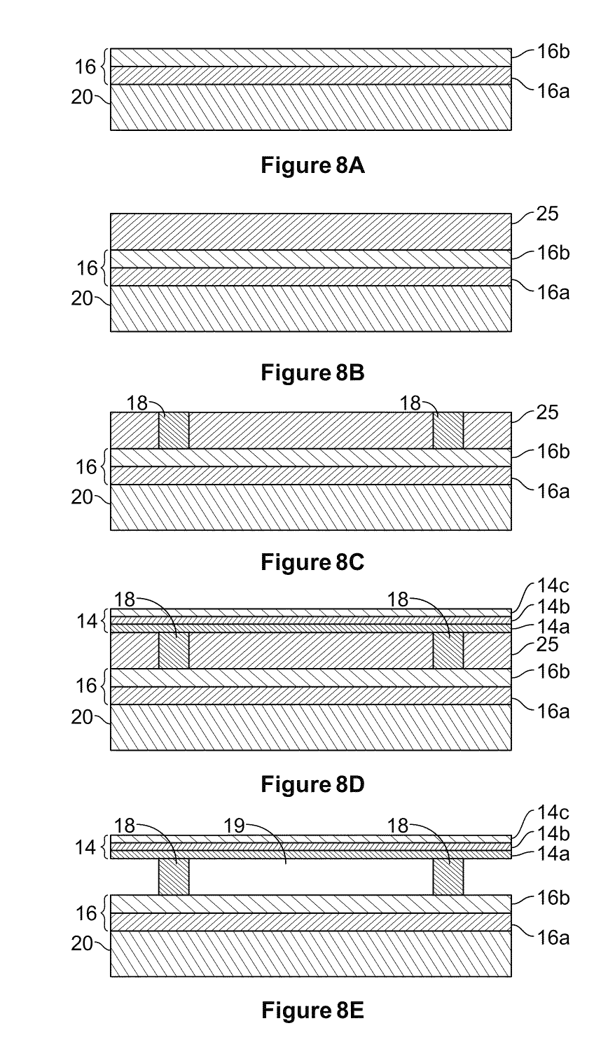

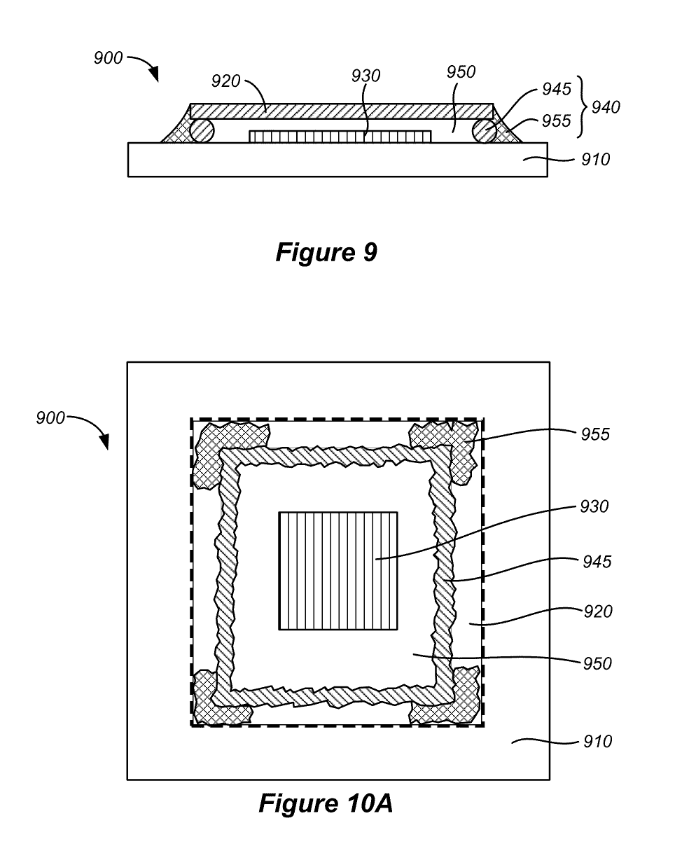

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture, e.g., interferometric modulators of the general type illustrated in FIGS. 1 and 6, in addition to other blocks not shown in FIG. 7. With reference to FIGS. 1, 6 and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, e.g., cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display.

The process 80 continues at block 84 with the formation of a sacrificial layer 25 over the optical stack 16. The sacrificial layer 25 is later removed (e.g., at block 90) to form the cavity 19 and thus the sacrificial layer 25 is not shown in the resulting interferometric modulators 12 illustrated in FIG. 1. FIG. 8B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (Si), in a thickness selected to provide, after subsequent removal, a gap or cavity 19 (see also FIGS. 1 and 8E) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 80 continues at block 86 with the formation of a support structure e.g., a post 18 as illustrated in FIGS. 1, 6 and 8C. The formation of the post 18 may include patterning the sacrificial layer 25 to form a support structure aperture, then depositing a material (e.g., a polymer or an inorganic material, e.g., silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning to remove portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 6 and 8D. The movable reflective layer 14 may be formed by employing one or more deposition processes, e.g., reflective layer (e.g., aluminum, aluminum alloy) deposition, along with one or more patterning, masking, and/or etching processes. The movable reflective layer 14 can be electrically conductive, and referred to as an electrically conductive layer. In some implementations, the movable reflective layer 14 may include a plurality of sub-layers 14a, 14b, 14c as shown in FIG. 8D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 also may be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, e.g., cavity 19 as illustrated in FIGS. 1, 6 and 8E. The cavity 19 may be formed by exposing the sacrificial material 25 (deposited at block 84) to an etchant. For example, an etchable sacrificial material such as Mo or amorphous Si may be removed by dry chemical etching, e.g., by exposing the sacrificial layer 25 to a gaseous or vaporous etchant, such as vapors derived from solid XeF₂ for a period of time that is effective to remove the desired amount of material, typically selectively removed relative to the structures surrounding the cavity 19. Other combinations of etchable sacrificial material and etching methods, e.g. wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

An EMS device can be packaged to withstand environmental forces and to limit the ingress of moisture and other environmental agents. The EMS device may have elements that are sensitive to external environmental factors, including temperature, pressure, humidity, contaminants, vibration, and impact. For example, the ingress of moisture can introduce “stiction” into the EMS device, which refers to the tendency of a movable layer to stick to a substrate or stationary layer in an electromechanical system. This can be a significant reliability concern for the electromechanical system. In some implementations, an EMS device may be protected from ambient conditions by a hermetic seal. A hermetic seal substantially prevents air and water vapor from flowing through the seal, acting as a barrier between the external environment and the EMS device. Also, in some implementations, an EMS device may be protected from contaminant gases by a seal material that has low outgassing. Furthermore, in some implementations, the EMS device may be protected by a mechanically strong seal that does not delaminate or break apart over time. Packaging techniques for an EMS device are described in more detail below.

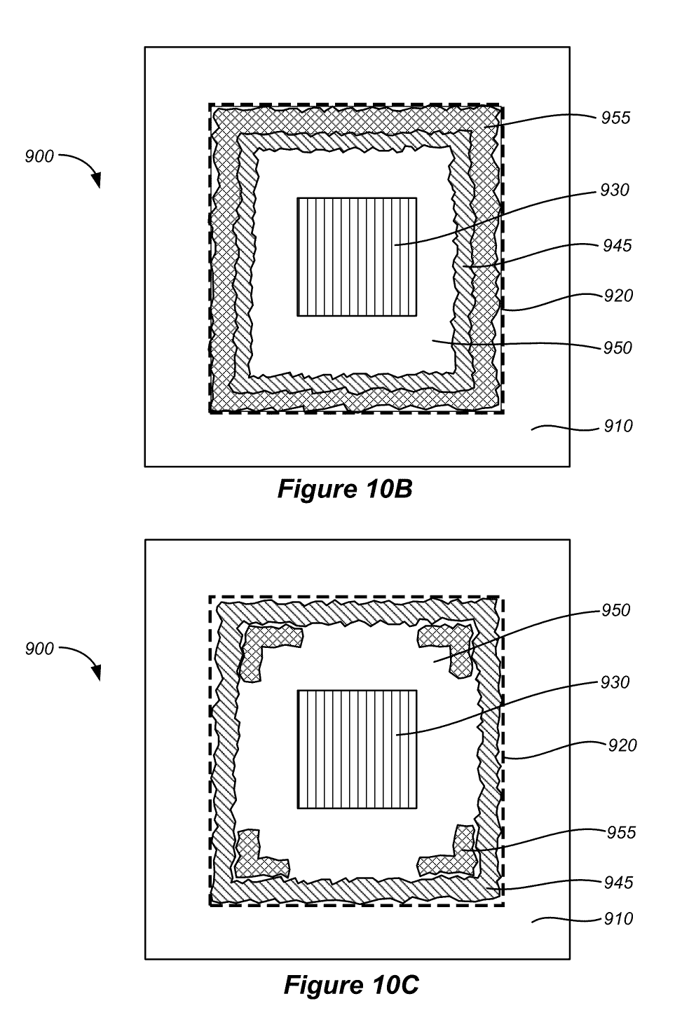

FIG. 9 shows an example of a cross-sectional side view of an EMS device with a primary seal and a secondary seal. In FIG. 9, a basic package structure for the EMS device 900 is shown. The EMS device 900 includes a substrate 910 and a cover plate 920, with an EMS device element 930 formed or otherwise disposed on the substrate 910. The cover plate 920 can also be referred to as a cover glass, back glass, backplate, or backplane. While the cover plate 920 in the example in FIG. 9 is shown without a recess, in some implementations, the cover plate 920 can include a recess to accommodate the EMS device element 930.

The substrate 910 and the cover plate 920 can be joined by a sealant structure 940 to form the package structure so that the EMS device element 930 is encapsulated by the substrate 910, cover plate 920, and sealant structure 940. A cavity 950 is formed between the substrate 910 and cover plate 920. The cavity 950 can form a protected space in which mechanical parts of the EMS device element 930 can move. For example, the IMOD 12 in the example in FIG. 1 can be an EMS device element with mechanical parts that can move across a protected space. The IMOD 12 can include the movable reflective layer 14 that is actuated near or adjacent to optical stack 16 upon an applied voltage in one of the pixels, and the movable reflective layer 14 that is unactuated from the optical stack 16 and separated by the gap 19 in another one of the pixels.

In some implementations, the sealant structure 940 can include a primary seal 945 and a secondary seal 955. The primary seal 945 can also be referred to as a barrier seal. The material of the primary seal 945 can be selected according to its water vapor permeability properties and/or outgassing properties. The secondary seal 955 can also be referred to as a mechanical seal. The material of the secondary seal 955 can be selected for its mechanical bonding strength.

The primary seal 945 can protect against moisture ingress by having a low water vapor permeability rate. The primary seal 945 can have a lower water vapor permeability rate than the secondary seal 955. As the lifetime of the EMS device 900 can at least in part be determined by the level of moisture within the EMS device 900, the primary seal 945 can increase the useable lifetime of the EMS device 900. Water vapor permeability rate of a material can be characterized in units of g/m²/day of water vapor that permeate across 0.1 mm thick membrane of a material at 60° C. and 90% humidity. In some implementations, the primary seal 945 includes an epoxy having a permeability of water vapor less than about 200 g/m²/day across a 0.1 mm thick membrane at 60° C. and 90% humidity, or less than about 20 g/m²/day across a 0.1 mm thick membrane at 60° C. and 90% humidity.

The primary seal 945 can limit contaminant gases entering the cavity 950 by having low outgassing. Outgassing can be measured by the percentage weight loss of material over time at a certain temperature. The lifetime of the EMS device 900 can at least in part be determined by the level of contaminant gases within the EMS device 900. In some implementations, the primary seal 945 includes an epoxy having an outgassing of less than about 0.5% by weight of the epoxy after 2 hours at 150° C., or less than about 0.1% by weight of the epoxy after 2 hours at 150° C.

The primary seal 945 can be made of any material having low permeability of water vapor and/or low outgassing. In some implementations, the primary seal 945 can include an organic material. For example, the organic material can be an epoxy, such as a high-purity bisphenol F epoxy. A high-purity epoxy can have less than about 10% by weight of impurities, or less than about 5%, 3%, 1%, or 0.1% by weight of impurities. In certain implementations, a high-purity epoxy can correspond to a lower amount of outgassing. UV-curable XNR5570 from Nagase Chemtex Corporation in Japan is one example of a high-purity bisphenol F epoxy. Other examples of organic materials can include polyisobutylene (sometimes referred to as butyl rubber or PIB), polyurethane, benzocyclobutylene (BCB), liquid crystal polymers, polyolefin and other thermal plastic resins. In some implementations, the primary seal 945 can include an inorganic material. Other primary seal examples can include but are not limited to thin film metal welds, liquid spin-on glass, solder, metal frits, printed metal, glass frits, and ceramic frits. The primary seal 945 can be a hermetic seal. Methods of hermetic sealing can include, but are not limited to, soldering, laser or resistive welding techniques, and anodic bonding techniques.

In some implementations, the primary seal 945 can contain inorganic particulate fillers. The inorganic particulates may provide increased mechanical strength and/or increased protection against moisture ingress. In some implementations, the primary seal 945 includes inorganic particulates having greater than about 20% by weight of the total weight of the primary seal 945. The primary seal 945 alone may not act as a suitable environmental barrier. Not only may it allow moisture and other contaminants into the EMS device 900 over time, but it may also lack sufficient mechanical strength to adhere to the cover plate 920 and the substrate 910 when subject to environmental forces. The mechanical strength of the primary seal 945 alone may also degrade over time upon exposure to moisture and heat.

The secondary seal 955 can provide mechanical strength to the sealant structure 940, such that the sealant structure does not delaminate or break apart. The lifetime of the EMS device 900 can at least in part be determined by the mechanical strength of the sealant structure 940. In particular implementations, the sealant structure 940 can have a high peel force strength. Peel force strength is the measure of the average force (force per unit width) to pull apart two bonded materials. The peel force can be measured by standard peeling test using flexible substrates. A tensile machine pulls the EMS device 900 with the sealant structure 940 using two metal plates secured to the EMS device 900 with high strength adhesive tape. The maximum force needed to pull the sealant structure 940 off of the EMS device 900 is measured. The material of the secondary seal 955 can be selected so that the sealant structure 940 has a high peel force strength when adhered to glass. In some implementations, the sealant structure 940 can have a peel force strength higher than 33 N/cm.

The secondary seal 955 can also provide moisture and heat resistance to the sealant structure 940. The moisture and heat resistance of the sealant structure 940 corresponds to how much the mechanical strength of the sealant structure 940 degrades over time in the presence of high concentrations of moisture and high temperature levels. In some implementations, the sealant structure 940 has a peel force strength higher than 10 N/cm after 10 days at 60° C. and 90% humidity, such as higher than 22 N/cm after 10 days at 60° C. and 90% humidity.

The secondary seal 955 can also add protection against moisture ingress to the sealant structure 940. In some implementations, the secondary seal 955 can provide an extra barrier to water vapor over the primary seal 945 alone. Hence, the entirety of the primary seal 945 and the secondary seal 955 can have a lower permeability of water vapor relative to the primary seal 945 by itself.

The secondary seal 955 can also add protection against contaminant gases and moisture from reacting with the primary seal 945. If contaminant gases or moisture reacts with the primary seal 945, this could lead to increased outgassing, increased degradation and increased swelling of the primary seal 945. Also, the secondary seal 955 can add an additional layer of protection against contaminant gases from entering the cavity 950.

The secondary seal 955 can include an adhesive selected for its mechanical strength, resistance against heat, resistance against moisture, and its improved protection against moisture ingress when combined with the primary seal 945. Adhesives can include but are not limited to epoxides, one-part epoxies, and two-part epoxies. Examples can include thermally curable Masterbond 10AOHT from Master Bond Inc. in Hackensack, N.J., Loctite® metal/concrete epoxy from Loctite® in Westlake, Ohio, 3M Scotch-Weld™ Epoxy Adhesives DP420 and DP460 from 3M in St. Paul, Minn. Additional examples of one-part or two-part epoxy adhesives for the secondary seal 955 can include polyurethane, hot-melt adhesives (HMA), and one-part or two-part acrylates.

The secondary seal 955 can include a high content of inorganic particulates that can be dispersed within the secondary seal 955. For example, Masterbond 10AOHT can contain inorganic particulates of aluminum oxide and Loctite® metal/concrete epoxy can contain inorganic particulates of calcium oxide. In some implementations, the inorganic particulates can be greater than 50% by weight of the total weight of the secondary seal 955, or greater than 75% by weight of the total weight of the secondary seal 955. As discussed earlier herein, the presence of inorganic particulates can increase mechanical strength and/or protection against moisture ingress.

In addition, the secondary seal 955 can include coupling agents or adhesion promoters. Adhesion promoters are materials that can covalently connect to both inorganic substrates and organic resins. In some implementations, the adhesion promoters include silanes. Other examples of adhesion promoters include organometallic compounds, such as zirconium-containing compounds and titanium-containing compounds.

An example of a silane adhesion promoter for an epoxy-based adhesive is 3-glycidoxypropyltrimethoxysilane (GPS). GPS can increase mechanical strength by forming chemical bonds with both epoxy resins and inorganic substrates, such as glass. GPS can also increase resistance against degradation of mechanical strength in the presence of moisture and heat. However, because GPS is volatile and can have a tendency to react with moisture to produce alcohols, GPS can lead to increased outgassing. As a result, in some implementations, the primary seal 945 does not include GPS. However, in combination with a primary seal 945 having low outgassing, a secondary seal 955 including GPS (with or without other materials mixed together) can provide for a high mechanical strength secondary seal 955 that is disposed outside the cavity 950 so that high outgassing does not degrade the performance of the EMS device element 930.

Table I illustrates a comparison between an adhesive based on high-purity bisphenol F epoxy without GPS and the same adhesive based on high-purity bisphenol F epoxy except with GPS. The epoxy without GPS had at least about 30% less peel force strength and degraded more significantly on exposure to humidity and heat. While the epoxy with GPS exhibited greater peel force strength and less degradation on exposure to humidity and heat, it outgassed more than about three times the amount of the same epoxy without GPS.

TABLE I

| | PEEL FORCE | OUTGASSING |
|---|---|---|
| | STRENGTH | (WEIGHT LOSS AFTER |
| ADHESIVE | (N/CM) | 150° C. BAKE FOR 2 HOURS) |
| Adhesive based on | 11 | 0.1% |
| bisphenol F epoxy | | |
| without GPS | | |
| Adhesive based on | 14 | 0.3% |
| bisphenol F epoxy | | |
| with GPS | | |

In some implementations, the primary seal 945 can be positioned around a perimeter of the EMS device 900 and in contact with the substrate 910 and the cover plate 920. The primary seal 945 can be continuous around the perimeter and provide a hermetically sealed environment inside the EMS device 900. The secondary seal 955 can be disposed outside the cavity 950, the cavity 950 being formed by the substrate 910, the cover plate 920, and the primary seal 945. In some implementations, the secondary seal 955 can be positioned around portions of an outer periphery of the primary seal 945 and in contact with the substrate 910 and the cover plate 920. The secondary seal 955 can be non-continuous around one or more corners of the outer periphery of the primary seal 945.

In some implementations, the primary seal 945 can include a first adhesive and the secondary seal 955 can include a second adhesive different from the first adhesive. The first adhesive can provide low outgassing and/or low permeability of water vapor while the second adhesive can provide mechanical strength that resist moisture and heat. In some implementations, the first adhesive can be a high-purity UV-curable epoxy and the second adhesive can be a thermally curable epoxy with a high concentration of particulate fillers.

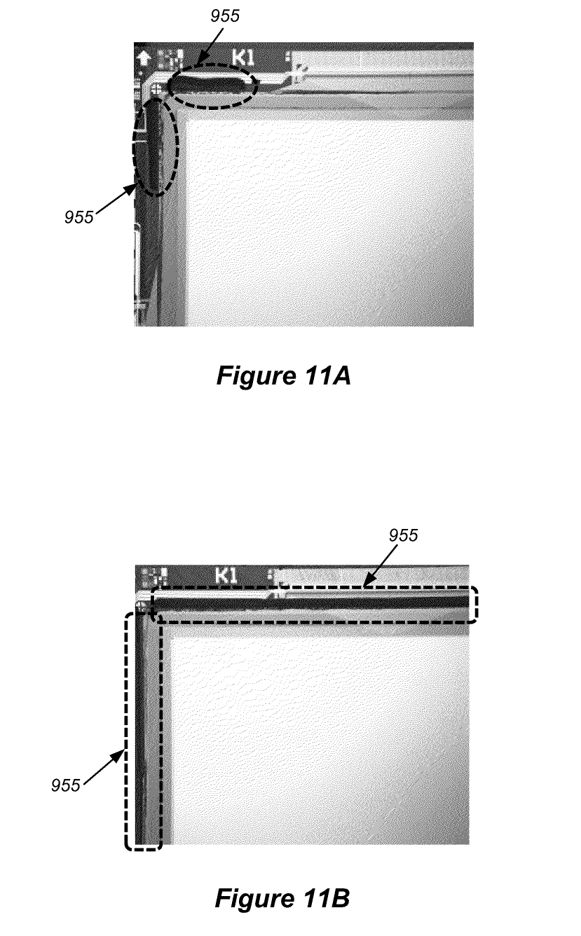

FIG. 10A shows an example of a top plan view of an EMS device with a primary seal and a secondary seal around all the corners of the primary seal according to some implementations. Generally, the corners of the EMS device 900 experiences increased amounts of stress, both intrinsic and extrinsic, relative to other parts of the EMS device 900. By providing a secondary seal 955 around the corners of the primary seal 945, the secondary seal 955 mechanically reinforces the sealant structure 940. Table II shows that a sealant structure 940 having a secondary seal 955 around all four corners of the primary seal 945 provides about 12 N/cm of additional peeling strength, and about 22 N/cm of additional strength after exposure to 240 hours of 60° C. and 90% relative humidity.

In some implementations, the secondary seal 955 can be continuous along the outer periphery of the primary seal 945. Hence, the secondary seal 955 can cover a substantial entirety of the outer periphery of the primary seal 945.

FIG. 10B shows an example of a top plan view of an EMS device with a primary seal and a secondary seal along the edges of the primary seal according to some implementations. By providing a secondary seal 955 along the edges of the primary seal 945, the secondary seal 955 mechanically reinforces the sealant structure 940 and increases protection against moisture ingress. Table II shows that a sealant structure 940 having a secondary seal 955 around the edges of the primary seal 945 provides about 16 N/cm of additional strength to the primary seal 945, and about 20 N/cm of additional strength after exposure to 240 hours of 60° C. and 90% relative humidity. Table II also shows that a sealant structure 940 having a secondary seal 955 around the edges of the primary seal 945 exhibits leakage resistance of about one order of magnitude more than the primary seal 945 alone after 200 hours. Thus, the secondary seal 955 can provide an improvement in leakage resistance by about one order of magnitude. Leakage resistance is the electrical resistance between parallel metal lines (not shown) inside the cavity 950 of the EMS device 900. The electrical resistance of the metal lines is sensitive to the moisture level. In Table II, a higher leakage resistance corresponds to reduced amounts of moisture entering the EMS device 900. In some implementations, the secondary seal 955 improves the hermeticity of the device package so that a device placed for 200 hours at 60° C. at 90% humidity will have one order of magnitude higher or more leakage resistance compared to a device with a primary seal 945 alone.

TABLE II

| | | | LEAKAGE |
|---|---|---|---|
| | | | RESISTANCE |
| | | PEEL FORCE (N) | (Ω) AFTER |
| | | AFTER 10 DAYS | 200 HOURS AT |
| | | AT 60° C. | 60° C. |
| SEALANT | PEEL FORCE | WITH 90% | WITH 90% |
| STRUCTURE | (N) AT T = 0 | HUMIDITY | HUMIDITY |
| Corner-Only | 47 N/cm | 33 N/cm | — |
| Masterbond | | | |
| Secondary Seal | | | |
| All-Edges | 51 N/cm | 31 N/cm | 1 × 10⁸ |
| Masterbond | | | |
| Secondary Seal | | | |
| No Secondary | 35 N/cm | 11 N/cm | 1 × 10⁷ |
| Seal | | | |

FIG. 10C shows an example of a top plan view of an EMS device with a primary seal and a secondary seal within the interior of the primary seal according to some implementations. The primary seal 945 can surround an entire periphery of the secondary seal 955 so that the secondary seal 955 is enclosed by the primary seal 945. In some implementations, the secondary seal 955 is disposed around the corners of the inner periphery of the primary seal 945. In other implementations, the secondary seal 955 is disposed around the edges of the inner periphery of the primary seal 945.

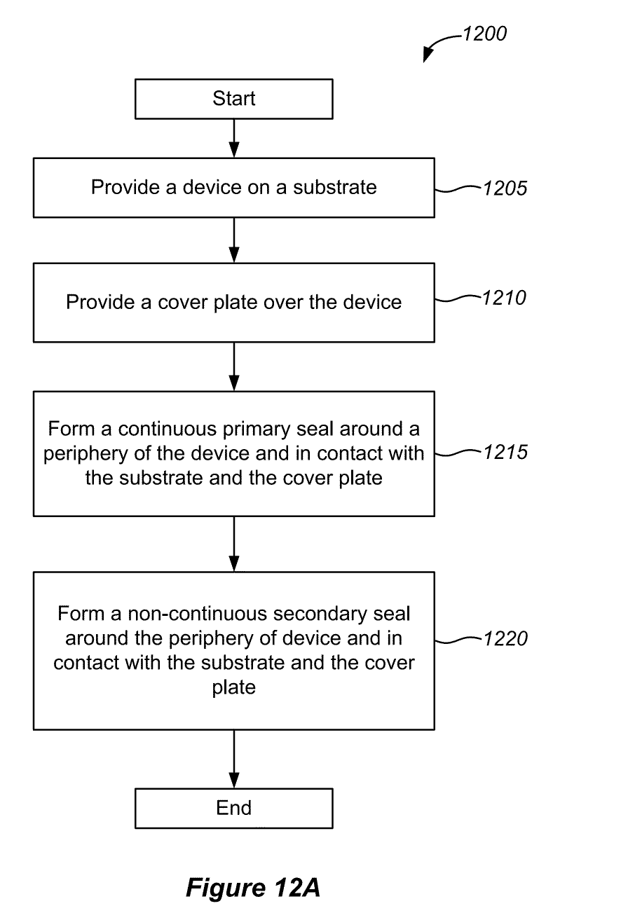

FIG. 11A shows an example of an image of a portion of an EMS device with a secondary seal around the corners of a primary seal according to some implementations. Each of the primary seal 945 and the secondary seal 955 can have a thickness between about 5 μm and 20 μm. It will be understood that the thickness of the primary seal 945 and the secondary seal 955 will depend on various factors, including the estimated lifetime of the EMS device 900, the material of the primary seal 945 and the secondary seal 955, the amount of contaminants and moisture that are estimated to permeate into the cavity 950 during the lifetime, the humidity of the ambient environment, and the thickness of the cover plate 920.

As shown in FIG. 11A, the secondary seal 955 is non-continuous around the corners of the primary seal 945. In some implementations, the secondary seal 955 can extend along more than about 5% of the length of one of the sides of the primary seal 945, such as about 8%, 10%, 15%, 25%, 35%, or 50% of the length of one of the sides of the primary seal 945. Hence, if a primary seal 945 has a length of 50 mm along one of its sides, the secondary seal 955 can be more than about 2.5 mm around the corners of the primary seal 945, such as about 4 mm, 5 mm, 7.5 mm, 10 mm, 12.5 mm, 17.5 mm, or 25 mm around the corners of the primary seal 945.

FIG. 11B shows an example of an image of a portion of an EMS device with a secondary seal along the edges of a primary seal according to some implementations. In some implementations, the secondary seal 955 is continuous around the corners and edges of the primary seal 945. In some implementations as shown in FIG. 11B, the secondary seal 955 is non-continuous around the corners but continuous along the edges of the primary seal 945.

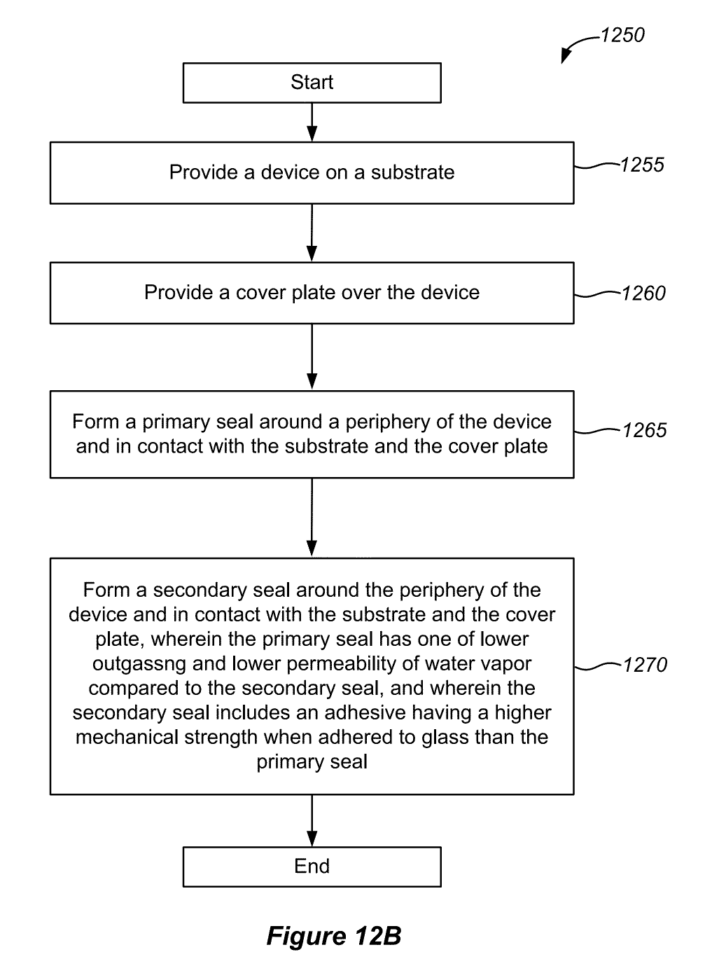

FIGS. 12A and 12B show examples of flow diagrams illustrating methods of manufacturing or packaging a device. In some implementations, the device is an EMS device, such as an EMS device as discussed earlier herein with respect to FIGS. 9-11B. Some of the blocks may be present in a process for manufacturing a device, along with other blocks not shown in FIGS. 12A and 12B. For example, it will be understood that additional processes of packaging and/or encapsulating the device may be present.

In FIG. 12A, the process 1200 begins at block 1205 where a device on a substrate is provided. In some implementations, the device can be an EMS device. While the remainder of the discussion of FIGS. 12A and 12B will focus on implementations with an EMS device, it is understood that packages can be made using primary and secondary seals as disclosed herein for devices that are not EMS devices. In some implementations, the substrate can be transparent and made of glass, plastic, or other transparent material. In some implementations, the substrate can be non-transparent or semi-transparent and made of silicon, metal, ceramic, alloy, or other suitable material. In some implementations, the device can be a display such as a reflective display, a transmissive display, or a self-emitting display. For example, the reflective display can be an IMOD. The IMOD can include a number of optical, mechanical, and electrical components, as discussed earlier herein.

The process 1200 continues at block 1210 where a cover plate is provided over the device. The cover plate can be a cover glass, a back plate, or a back glass for the device. The cover plate can rest on a support structure, which can include a spacer and/or sealant structure as described earlier herein. The cover plate can include one or more types of materials, for example, glass, metal, foil, stainless steel, polymer, plastic, ceramic, or semiconductor material such as silicon. The cover plate can provide protection for the device from ambient conditions, such as temperature, pressure, and other environmental conditions.

The process 1200 continues at block 1215 where a continuous primary seal around a periphery of the device and in contact with the substrate and the cover plate is formed. In some implementations, the primary seal can form a hermetic seal for the device inside. Forming the primary seal can be achieved using any appropriate sealing technique, such as dispensing and curing the primary seal. Dispensing can include injecting a liquid or semi-liquid solution with a syringe, which can be followed by one or more post-dispensation operations to solidify the solution, such as a UV cure or thermal cure. In some implementations, dispensing the primary seal can include printing. Printing can include one of many printing procedures, such as lithographic printing, screen printing, or inkjet printing.

The formation of the primary seal around the perimeter of the device is part of the packaging process of the device, and this packaging process can be achieved in a vacuum, pressure between a vacuum up to and including ambient pressure, normal atmospheric pressure conditions, or pressure higher than ambient pressure. The packaging process may also be accomplished in an environment of varied and controlled high or low pressure during the sealing process. The packaging process may be achieved in a substantially dry environment.

The process 1200 continues at block 1220 where a non-continuous secondary seal around the periphery of the device and in contact with the substrate and the cover plate is formed. In some implementations, the secondary seal is formed around one or more corners of an outer periphery of the primary seal. Forming the secondary seal can be achieved using any appropriate sealing technique. In some implementations, the adhesive can be dispensed in a liquid or semi-liquid state between the substrate and the cover glass. Dispensing the adhesive can include but is not limited to casting, injection molding, masking and spraying, or printing. In some examples, dispensing can be achieved using a syringe. Additionally, forming the secondary seal can also include curing the adhesive. Curing can include but is not limited to a thermal cure, a time-based cure, a radiation cure such as a UV cure, a moisture cure, or air (oxygen) dry. In some implementations, forming the secondary seal can be performed after the packaging process is completed, such as when the primary seal is formed around the perimeter of the EMS device. In other implementations, forming the secondary seal can be performed concurrently with the packaging process.

FIG. 12B shows an example of a flow diagram illustrating a method of manufacturing or packaging a device. The process 1250 begins at blocks 1255 and 1260, which can be similar to blocks 1205 and 1210, respectively, as described with respect to FIG. 12A.

The process 1250 continues at block 1265 where a primary seal is formed around a periphery of the device and in contact with the substrate and the cover plate, which can be similar to block 1215 in FIG. 12A. In block 1265, the primary seal can have at least one of a low outgassing and a low permeability of water vapor. In some implementations, forming the primary seal includes forming a continuous primary seal that provides a hermetically sealed environment inside.

The process 1250 continues at block 1270 where a secondary seal is formed around the periphery of the device and in contact with the substrate and the cover plate, which can be similar to block 1220 in FIG. 12A. In some implementations, the secondary seal is non-continuous. In some implementations, the secondary seal is formed around one or more corners of an outer periphery of the primary seal. In block 1270, the secondary seal can include an adhesive having a higher mechanical strength when adhered to glass than the primary seal. In block 1270, the primary seal has at least one of lower outgassing and lower permeability of water vapor than the secondary seal. In some implementations, the secondary seal has a higher moisture and heat resistance than the primary seal.

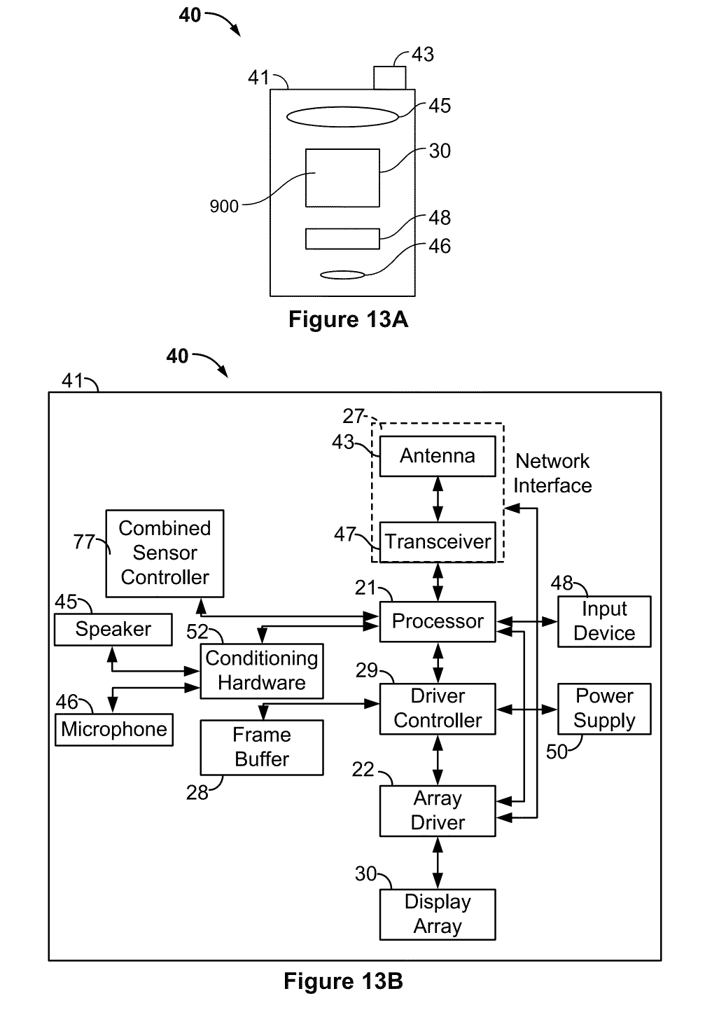

FIGS. 13A and 13B show examples of system block diagrams illustrating a display device 40 that includes a plurality of interferometric modulators. The display device 40 can be, for example, a cellular or mobile telephone. However, the same components of the display device 40 or slight variations thereof are also illustrative of various types of display devices such as televisions, e-readers and portable media players.

The display device 40 includes a housing 41, a display 30, an antenna 43, a speaker 45, an input device 48, and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber, and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein. In some implementations, the EMS device element as discussed earlier herein with respect to FIGS. 9-11B can form the display 30.

The components of the display device 40 are schematically illustrated in FIG. 13B. Such components can form part of the EMS device apparatus as discussed earlier herein with respect to FIGS. 9-11B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 can provide power to all components as required by the particular display device 40 design.

The network interface 27 includes the antenna 43 and the transceiver 47 so that the display device 40 can communicate with one or more devices over a network. The network interface 27 also may have some processing capabilities to relieve, e.g., data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g or n. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation, and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (e.g., an IMOD controller). Additionally, the array driver 22 can be a conventional driver or a bi-stable display driver (e.g., an IMOD display driver). Moreover, the display array 30 can be a conventional display array or a bi-stable display array (e.g., a display including an array of IMODs). In some implementations, the driver controller 29 can be integrated with the array driver 22. Such an implementation is common in highly integrated systems such as cellular phones, watches and other small-area displays

In some implementations, the input device 48 can be configured to allow, e.g., a user to control the operation of the display device 40. The input device 48 can include a keypad, such as a QWERTY keyboard or a telephone keypad, a button, a switch, a rocker, a touch-sensitive screen, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices as are well known in the art. For example, the power supply 50 can be a rechargeable battery, such as a nickel-cadmium battery or a lithium-ion battery. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those having ordinary skill in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An electromechanical systems apparatus, comprising:
a substrate;
an electromechanical systems device element disposed on the substrate;
a cover plate over the electromechanical systems device element; and
a sealant structure including:
a primary seal positioned around a perimeter of the electromechanical systems device and in contact with the substrate and the cover plate; and
a secondary seal positioned around portions of an outer periphery of the primary seal and in contact with the substrate and the cover plate, wherein the primary seal has lower outgassing compared to the secondary seal, and wherein the secondary seal includes an adhesive having a higher mechanical strength when adhered to glass compared to the primary seal.

2. The electromechanical systems apparatus of claim 1, wherein the secondary seal is positioned only around one or more corners of the outer periphery of the primary seal.

3. The electromechanical systems apparatus of claim 1, wherein the secondary seal has a higher moisture and heat resistance than the primary seal.

4. The electromechanical systems apparatus of claim 1, wherein the first epoxy has an outgassing of less than about 0.1% by weight of the first epoxy after 2 hours at 150° C.

5. The electromechanical systems apparatus of claim 1, wherein the primary seal has lower permeability of water vapor compared to the secondary seal, and wherein the primary seal includes a first epoxy having a permeability of water vapor less than about 20 g/m²/day across a 0.1 mm thick membrane at 60° C. and 90% humidity.

6. The electromechanical systems apparatus of claim 1, wherein the sealant structure has a peel force strength higher than 22 N/cm after 10 days at 60° C. and 90% humidity.

7. The electromechanical systems apparatus of claim 1, wherein the secondary seal includes inorganic particulates having greater than about 75% by weight of the total weight of the secondary seal.

8. The electromechanical systems apparatus of claim 1, wherein the secondary seal includes silane-containing adhesion promoters.

9. The electromechanical systems apparatus of claim 1, wherein the sealant structure has a lower permeability of water vapor relative to the primary seal.

10. The electromechanical systems apparatus of claim 1, wherein the primary seal includes a high-purity bisphenol F epoxy.

11. The electromechanical systems apparatus of claim 1, wherein the primary seal includes inorganic particulates having greater than about 20% by weight of the total weight of the primary seal.

12. The electromechanical systems apparatus of claim 1, wherein the adhesive is a one-part epoxy.

13. The electromechanical systems apparatus of claim 1, wherein the adhesive is a two-part epoxy.

14. The electromechanical systems apparatus of claim 1, wherein the cover plate is a back glass for a MEMS display device, the MEMS display device including an interferometric modulator.

15. The electromechanical systems apparatus of claim 1, wherein the electromechanical systems device element forms a display, the display including: a processor that is configured to communicate with the display, the processor being configured to process image data; and a memory device that is configured to communicate with the processor.

16. The electromechanical systems apparatus of claim 15, further comprising:
a driver circuit configured to send at least one signal to the display; and
a controller configured to send at least a portion of the image data to the driver circuit.

17. The electromechanical systems apparatus of claim 15, further comprising:
an image source module configured to send the image data to the processor, wherein the image source module includes at least one of a receiver, transceiver, and transmitter.

18. The electromechanical systems apparatus of claim 15, further comprising:
an input device configured to receive input data and to communicate the input data to the processor.

19. An electromechanical systems apparatus, comprising:
a substrate;
an electromechanical systems device element formed on the substrate;
a cover plate over the electromechanical systems device element; and
a sealant structure including:
a continuous primary seal positioned around a perimeter of the electromechanical systems device and in contact with the substrate and the cover plate to provide a hermetically sealed environment inside, wherein the primary seal includes a first adhesive; and
a non-continuous secondary seal positioned proximate to one or more corners of a periphery of the primary seal and in contact with the substrate and the cover plate, wherein the secondary seal includes a second adhesive different than the first adhesive.

20. The electromechanical systems apparatus of claim 19, wherein the second adhesive has a higher mechanical strength when adhered to glass than the first adhesive.

21. The electromechanical systems apparatus of claim 19, wherein the sealant structure has a peel force strength higher than 22 N/cm after 10 days at 60° C. and 90% humidity.

22. The electromechanical systems apparatus of claim 19, wherein the secondary seal includes silane-containing adhesion promoters.

23. The electromechanical systems apparatus of claim 19, wherein the secondary seal includes inorganic particulates having greater than 75% by weight of the total weight of the secondary seal.

24. The electromechanical systems apparatus of claim 19, wherein the first adhesive has at least one of lower outgassing and lower permeability of water vapor than the second adhesive.

25. The electromechanical systems apparatus of claim 24, wherein the first adhesive includes an epoxy having an outgassing of less than about 0.1% by weight of the first epoxy after 2 hours at 150° C.

26. The electromechanical systems apparatus of claim 24, wherein the first adhesive includes an epoxy having a permeability of water vapor less than about 20 g/m²/day across a 0.1 mm thick membrane at 60° C. and 90% humidity.

27. The electromechanical systems apparatus of claim 24, wherein the secondary seal is positioned around one or more corners of one of an inner and an outer periphery of the primary seal.

28. An electromechanical systems apparatus, comprising:
a substrate;
an electromechanical systems device element formed on the substrate;
a cover plate over the electromechanical systems device element; and
a sealant structure including:
primary means for sealing the electromechanical systems device apparatus positioned around a perimeter of the electromechanical systems device and in contact with the substrate and the cover plate, wherein the primary means for sealing, the cover plate, and the substrate form a cavity within the electromechanical systems apparatus; and
secondary means for sealing the electromechanical systems device apparatus positioned outside the cavity and in contact with the substrate and the cover plate, wherein the primary means for sealing has lower outgassing compared to the secondary means for sealing, and wherein the secondary means for sealing includes an adhesive having a higher mechanical strength when adhered to glass compared to the primary means for sealing.

29. The electromechanical systems apparatus of claim 28, wherein the primary means for sealing has lower permeability of water vapor than the secondary means for sealing.

30. The electromechanical systems apparatus of claim 28, wherein the secondary means for sealing is positioned only around one or more corners of an outer periphery of the primary means for sealing.

31. A method of manufacturing an electromechanical systems apparatus, comprising:
providing an electromechanical systems device on a substrate;
providing a cover plate over the electromechanical systems device;
forming a primary seal around a periphery of the electromechanical systems device and in contact with the substrate and the cover plate; and
forming a secondary seal around the periphery of the electromechanical systems device and in contact with the substrate and the cover plate, wherein the primary seal has at least one of lower outgassing and lower permeability of water compared to the secondary seal, and wherein the secondary seal includes an adhesive having a higher mechanical strength when adhered to glass than the primary seal.

32. The method of claim 31, wherein the secondary seal has a higher moisture and heat resistance than the primary seal.

33. The method of claim 31, wherein forming the primary seal includes forming a continuous primary seal and providing a hermetically sealed environment inside the electromechanical systems apparatus, and wherein forming the secondary seal includes forming a non-continuous secondary seal.

34. The method of claim 31, wherein forming the non-continuous secondary seal includes:
dispensing a second epoxy in a liquid or semi-liquid state between the substrate and the cover glass; and
curing the second epoxy.

35. An electromechanical systems apparatus produced by the method as recited by claim 31.
